(19) United States
(12) Patent Application Publication
(10) Pub. No.: US 2022/0311441 A1
(43) Pub. Date: Sep. 29, 2022

(54) CAPACITIVE SENSING DEVICE

(71) Applicant: Egis Technology Inc., Hsinchu City (TW)

(72) Inventor: Shiue-Shin Liu, Hsinchu City (TW)

(73) Assignee: Egis Technology Inc., Hsinchu City (TW)

(21) Appl. No.: 17/638,177

(22) PCT Filed: Apr. 24, 2020
(86) PCT No.: PCT/CN2020/086636

§ 371 Date: Feb. 24, 2022

Related U.S. Application Data
(60) Provisional application No. 62/891,984, filed on Aug. 27, 2019.

(51) Int. Cl. H03K 17/96

(52) U.S. Cl. CPC H03K 17/962; H03K 2217/96074; H03K 2217/96071

(57) ABSTRACT

A capacitive sensing device is provided. A control circuit adjusts a capacitance value of an adjustable capacitor unit according to a digital sensing signal converted from a sensing signal by an analog-to-digital converter, such that the capacitance value of the adjustable capacitor unit approaches a background parasitic capacitor.

### TECHNICAL FIELD

The disclosure relates to a sensing device, and more particularly to a capacitive sensing device.

### DESCRIPTION OF RELATED ART

With the development of optoelectronic technology, proximity switching devices have been widely used in different machines, such as smart phones, ticketing systems for transportation vehicles, digital cameras, remote controls and liquid crystal displays. Common sensing devices capable of proximity switching include proximity sensors and capacitive touch switches. The capacitive touch switches determine the state of the switch by sensing the parasitic capacitor of its electrodes. However, the electrodes have the characteristics of an antenna, which will reflect changes in the electric field in the environment (such as changes in ambient humidity or the influence of radio frequency signals) and affect the sensing results of the capacitive touch switch, thereby causing sensing errors.

### SUMMARY

The disclosure provides a capacitive sensing device, which can improve the sensing quality of the capacitive sensing device, and avoid the situation where the sensing result of the capacitive sensing device is influenced by changes in the electric field in the environment, resulting in sensing errors.

A capacitive sensing device of the disclosure includes a sensing electrode, a sensing circuit, an analog-to-digital converter, and a control circuit. The sensing electrode is configured to receive a touch operation by a touch tool. The sensing circuit is configured to have an input terminal coupled to the sensing electrode through a sensing signal line and sense a change in a sensing capacitor between the touch tool and the sensing electrode to generate a sensing signal. The sensing circuit includes a first switch, a second switch, a third switch and an adjustable capacitor unit. The first switch is coupled between a power supply voltage and the input terminal. The second switch has one terminal coupled to the input terminal, and an other terminal of the second switch is coupled to an output terminal of the sensing circuit. The third switch is coupled between the other terminal of the second switch and a ground. The first switch, the second switch and the third switch periodically switch their being turned on and off, respectively. When the first switch and the third switch are turned on, the second switch is turned off, and when the second switch is turned on, the first switch and the third switch are turned off. The adjustable capacitor unit is coupled between the other terminal of the second switch and the ground. The analog-to-digital converter is coupled to the sensing circuit and configured to convert the sensing signal into a digital sensing signal. The control circuit is coupled to the sensing circuit and the analog-to-digital converter and configured to adjust a capacitance value of the adjustable capacitor unit according to the digital sensing signal, so that the capacitance value of the adjustable capacitor unit approaches a background parasitic capacitor.

Based on the above, the control circuit of the embodiment of the disclosure may adjust the capacitance value of the adjustable capacitor unit according to the digital sensing signal obtained by converting the sensing signal by the analog-to-digital converter, so that the capacitance value of the adjustable capacitor unit approaches the background parasitic capacitor.

In this way, it is possible to avoid the situation where the sensing result of the capacitive sensing device is influenced by the electric field change in the environment and has a sensing error, thereby improving the sensing quality of the capacitive sensing device.

In order to make the above-mentioned features and advantages of the disclosure more comprehensible, embodiments are described in detail below with the accompanying drawings.

### BRIEF DESCRIPTION OF THE DRAWINGS

FIG. 1 is a schematic diagram of a capacitive sensing device according to an embodiment of the disclosure.

FIG. 2 is a waveform diagram of a control signal of a capacitive sensing device according to the embodiment of FIG. 1 of the disclosure.

FIG. 3 is a schematic diagram of an adjustable capacitor unit according to an embodiment of the disclosure.

FIG. 4 is a schematic diagram of a capacitive sensing device according to another embodiment of the disclosure.

FIG. 5 is a schematic diagram of a capacitive sensing device according to another embodiment of the disclosure.

FIG. 6 is a waveform diagram of a control signal of a capacitive sensing device according to the embodiment of FIG. 5 of the disclosure.

### DESCRIPTION OF EMBODIMENTS

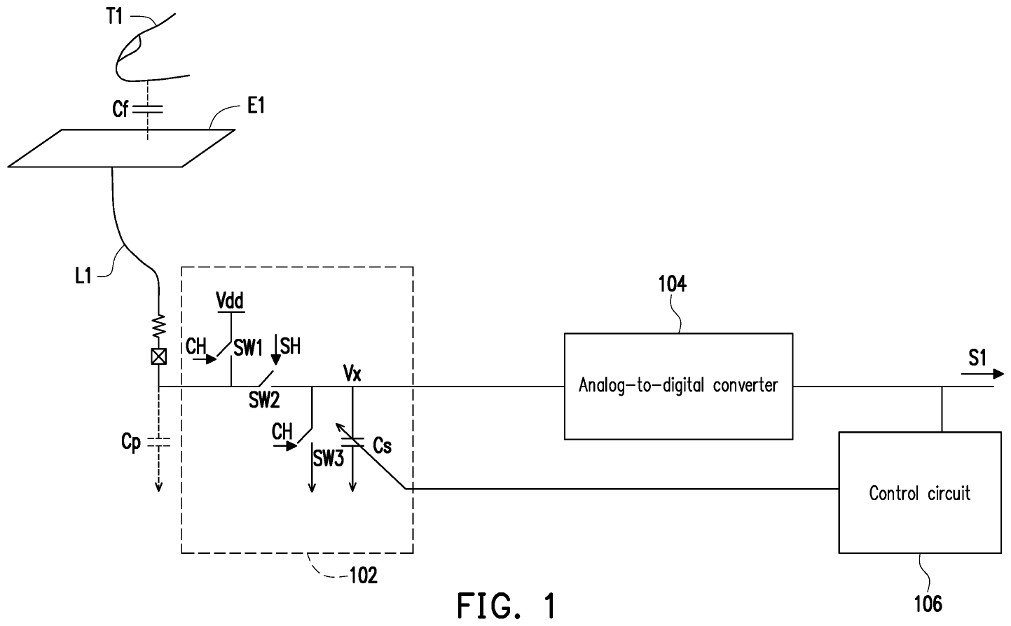

FIG. 1 is a schematic diagram of a capacitive sensing device according to an embodiment of the disclosure. Please refer to FIG. 1. The capacitive sensing device includes a sensing electrode E1, a sensing circuit 102, an analog-to-digital converter 104 and a control circuit 106. The sensing electrode E1 may be coupled to the input terminal of the sensing circuit 102 through a sensing signal line L1, and the analog-to-digital converter 104 is coupled to the output terminal of the sensing circuit 102 and the control circuit 106.

The sensing electrode E1 may be used to receive the touch operation of a touch tool T1, and for example, in this embodiment, it may receive the touch operation of a finger, but it is not limited thereto. The sensing circuit 102 may sense the capacitance change of a sensing capacitor Cf between the touch tool T1 and the sensing electrode E1 to generate a sensing signal to the analog-to-digital converter 104. The analog-to-digital converter 104 may convert the sensing signal provided by the sensing circuit 102 into a digital sensing signal Si and provide it to a subsequent circuit for analysis and processing.

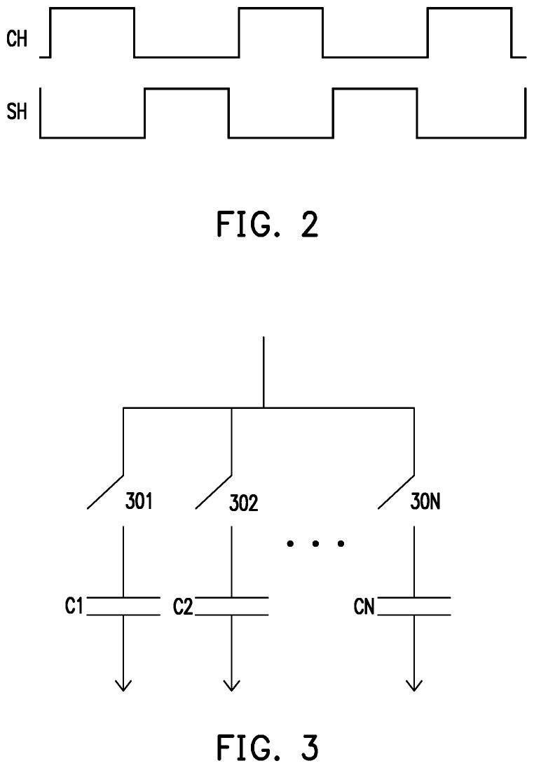

Further, the sensing circuit 102 may include switches SW1 to SW3 and an adjustable capacitor unit Cs. The switch SW1 is coupled between a power supply voltage Vdd and the input terminal of the sensing circuit 102. The switch SW1 is coupled between the input terminal and the output terminal of the sensing circuit 102. The switch SW3 is coupled between the output terminal of the sensing circuit 102 and the ground. The adjustable capacitor unit Cs is coupled between the output terminal of the sensing circuit 102 and the ground. The switches SW1 and SW3 may be controlled by a control signal CH to periodically switch between being turned on and being turned off, and the switch SW2 may be controlled by a control signal SH to periodically switch between being turned on and being turned off. The waveforms of the control signals CH and SH may be as shown in FIG. 2. When the switches SW1 and SW3 are turned on (when the control signal CH is at a high voltage level), the switch SW2 is turned off (the control signal SH is at a low voltage level), and when the switch SW2 is turned on (when the control signal CH is at a high voltage level), the switches SW1 and SW3 are turned off (the control signal CH is at a low voltage level).

When the switches SW1 and SW3 are turned on and the switch SW2 is turned off, the power supply voltage Vdd may reset the voltage of a background parasitic capacitor Cp, and the adjustable capacitor unit Cs may be discharged through the switch SW3 to reset the voltage of the adjustable capacitor unit Cs. The background parasitic capacitor Cp may include, for example, the parasitic capacitor of the electrode E1 to the ground, the parasitic capacitor of the sensing signal line L1 to the ground, and the parasitic capacitor of a touch panel of the capacitive sensing device to the ground, but is not limited thereto. After that, when the switches SW1 and SW3 are turned off and the switch SW2 is turned on, the background parasitic capacitor Cp shares the charge with the adjustable capacitor unit Cs through the switch SW2, and the sensing information stored in the background parasitic capacitor Cp is transmitted to the adjustable capacitor unit Cs, and a sensing voltage Vx (i.e., a sensing signal) is generated on the adjustable capacitor unit Cs. In more detail, the sensing voltage Vx may be expressed by the following formula (1):

$${V}_{X} = \frac{Cp + Cf}{Cp + Cf + Cs} {V}_{dd} \qquad ( 1 )$$

In the case where the background parasitic capacitor Cp is much larger than the capacitance value of the sensing capacitor Cf, when Vx is equal to ½ Vdd, that is, when the capacitance value of the adjustable capacitor unit Cs is equal to the capacitance value of the background parasitic capacitor Cp, the capacitive sensing device has the best sensing sensitivity. The control circuit 106 may adjust the capacitance value of the adjustable capacitor unit Cs according to the digital sensing signal S1, so that the capacitance value of the adjustable capacitor unit Cs approaches the background parasitic capacitor Cp, so as to ensure that the capacitive sensing device has the best sensing sensitivity, and that the capacitive sensing device does not have sensing errors due to changes in environmental conditions or the influence of radio frequency signals. For example, when the sensing voltage Vx increases due to changes in environmental conditions, the control circuit 106 may increase the capacitance value of the adjustable capacitor unit Cs according to the digital sensing signal S1 to resist the influence caused by changes in environmental conditions.

The adjustable capacitor unit Cs may be implemented, for example, in the manner of the embodiment in FIG. 3, and the adjustable capacitor unit Cs may include multiple switches 201 to 20N and capacitors C1 to CN, each of which is connected in series with the corresponding capacitor between the output terminal of the sensing circuit 102 and the ground. The turning on and off of switches 301 to 30N may be controlled by the control circuit 106 to adjust the capacitance value of the adjustable capacitor unit Cs. In some embodiments, the control circuit 106 may be implemented by, for example, a digital integrating circuit, which may integrate the digital sensing signal S1, and generate a bit signal according to the integrated value to control the turning on and off of the switches 301 to 30N, thereby adjusting the capacitance value of the capacitor unit Cs. For example, the digital integrating circuit may generate an integrated value according to the digital sensing signal S1, and adjust the capacitance value of the adjustable capacitor unit Cs according to the integrated value and the target value. For example, when the integrated value is higher than the target value, it means that the sensing voltage Vx is too large, and the control circuit 106 may increase the capacitance value of the adjustable capacitor unit Cs. When the integrated value is lower than the target value, it means that the sensing voltage Vx is too small, and the control circuit 106 may decrease the capacitance value of the adjustable capacitor unit Cs.

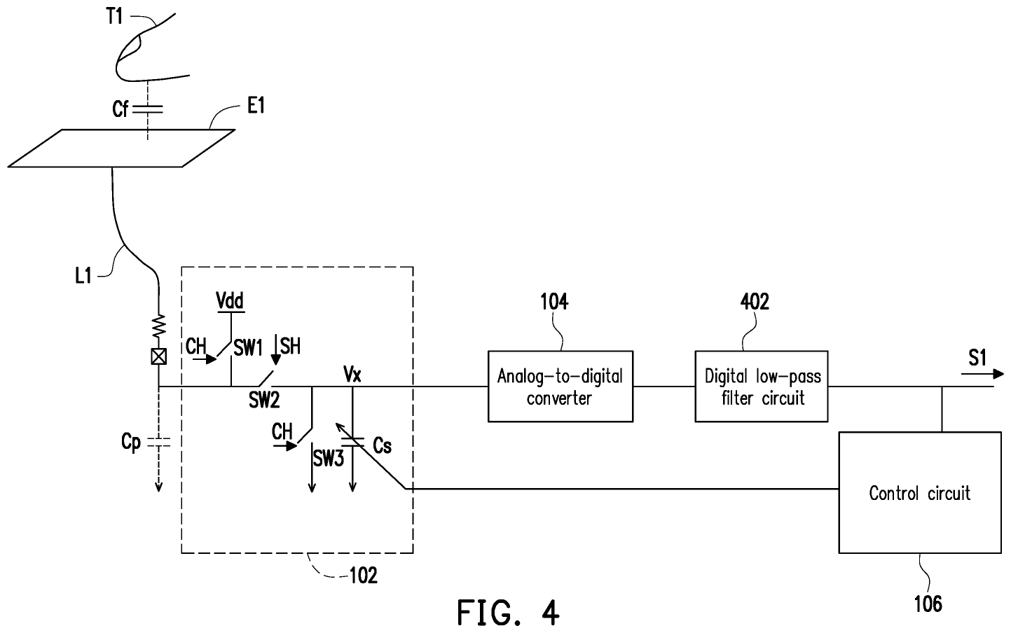

FIG. 4 is a schematic diagram of a capacitive sensing device according to another embodiment of the disclosure. Please refer to FIG. 4. The difference between the capacitive sensing device of this embodiment and the capacitive sensing device of the embodiment of FIG. 2 is that the capacitive sensing device of this embodiment further includes a digital low-pass filter circuit 402. The digital low-pass filter circuit 402 is coupled between the analog-to-digital converter 104 and the control circuit 106. The digital low-pass filter circuit 402 may perform low-pass filtering to remove high-frequency noise of the digital sensing signal S1 and further prevent the sensing result from being interfered by radio frequency signals.

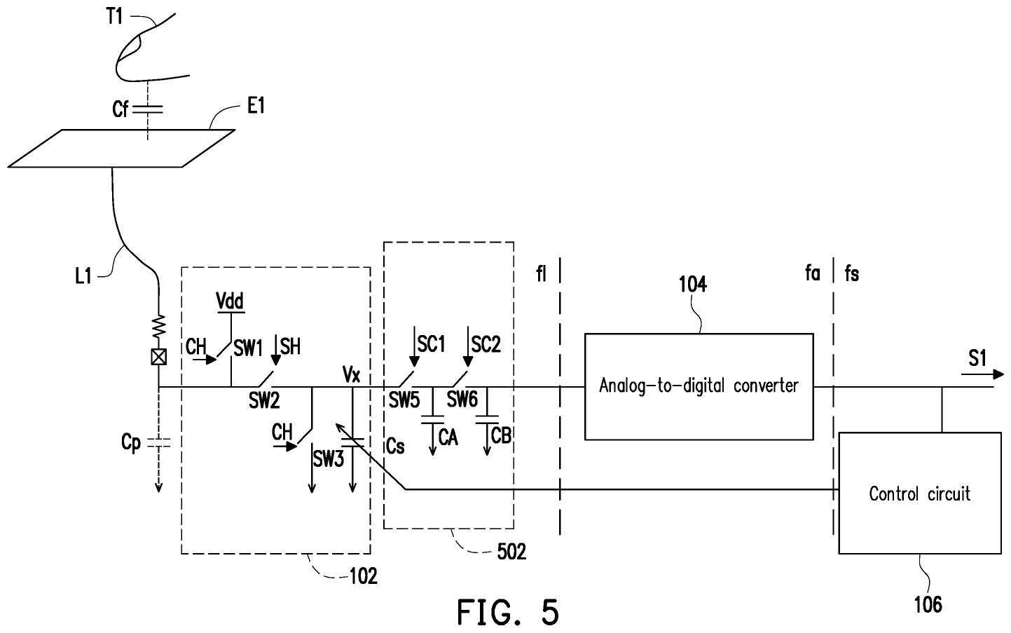

FIG. 5 is a schematic diagram of a capacitive sensing device according to another embodiment of the disclosure. Please refer to FIG. 5. The difference between the capacitive sensing device of this embodiment and the capacitive sensing device of the embodiment of FIG. 2 is that the capacitive sensing device of this embodiment further includes a switched capacitance low-pass filter circuit 502. The switched capacitance low-pass filter circuit 502 is coupled to between the sensing circuit 102 and the analog-to-digital converter 104 to perform low-pass filtering on the sensing signal provided by the sensing circuit 102. Specifically, the switched capacitance low-pass filter circuit 502 may include switches SW5 and SW6 and capacitors CA and CB. The switches SW5 and SW6 are connected in series between the output terminal of the sensing circuit 102 and the analog-to-digital converter 104, and the capacitor CA is coupled between the common contact of the switches SW5 and SW6 and the ground, the capacitor CB is coupled between the common contact of the switch SW6 and the analog-to-digital converter 104 and the ground. The capacitance value of the capacitor CB is greater than the capacitance value of the capacitor CA. For example, when the capacitance value of the background parasitic capacitor Cp is 1 to 64 picofarads (pF), the capacitance value of the capacitor CB may be, for example, 1 to 4 picofarads, and the capacitance value of the capacitor CA may be, for example, 50 femtofarads (fF), but the disclosure is not limited thereto.

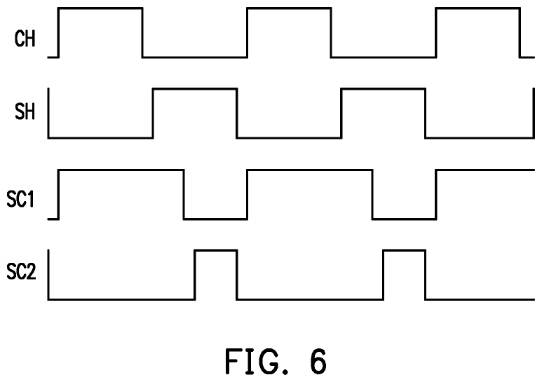

The switches SW5 and SW6 are controlled by control signals SC1 and SC2 to change their being turned on and off. The waveforms of the control signals CH, SH, SC1 and SC2 may be as shown in FIG. 6. The implementation of the sensing circuit 102 is the same as that of the embodiment in FIG. 1, and thus the description will not be repeated here. In the switched capacitance low-pass filter circuit 502, when the switch SW5 is turned on, the switch SW6 is turned off. During the period when the switch SW5 is turned on, when the switch SW3 is turned on, the capacitor CA may be reset by discharging to the ground through the switch SW3, and when the switch SW2 is turned on, it may receive the stored sensing information from the background parasitic capacitor Cp; that is, it may receive the sensing signal provided by the sensing circuit 102. After that, when the switch SW6 is turned on and the switch SW5 is turned off, the capacitor CA transmits the stored sensing information to the capacitor CB to complete the low-pass filtering of the sensing signal.

The analog-to-digital converter 104 may perform analog-to-digital conversion on the voltage on the capacitor CB to generate a digital sensing signal. The control circuit 106 may adjust the capacitance value of the adjustable capacitor unit Cs according to the digital sensing signal 51 as described in the embodiment of FIG. 2, so that the capacitance value of the adjustable capacitor unit Cs approaches the background parasitic capacitor Cp, so as to ensure the capacitive sensing device has the best sensing sensitivity, and does not have sensing errors due to changes in environmental conditions or the influence of radio frequency signals.

It is worth noting that the operating frequency fa of the analog-to-digital converter 104 of this embodiment may be lower than the operating frequency f1 of the sensing circuit 102 and the switched capacitance low-pass filter circuit 502, and the operating frequency fs of the control circuit 106 may be lower than the operating frequency fa of the analog-to-digital converter 104. For example, the operating frequency f1 of the sensing circuit 102 and the switched capacitance low-pass filter circuit 502 may be, for example, 1 MHz; the operating frequency fa of the analog-to-digital converter 104 may be 500 Hz; and the operating frequency fs of the control circuit 106 may be 50 Hz. That is, after the switched capacitance low-pass filter circuit 502 receives the sensing signal provided by the sensing circuit 102 for 20 times, the analog-to-digital converter 104 samples the voltage on the capacitor CB once. Similarly, after the analog-to-digital converter 104 performs 10 analog-to-digital conversions, the control circuit 106 samples the digital sensing signal 51 accumulated by the analog-to-digital converter 104. Since the power consumed by the operation of the switched capacitance low-pass filter circuit 502 is very low, the power consumption of the capacitive sensing device is not greatly affected, and high-frequency noise may also be effectively removed. In this way, making the operating frequency of the analog-to-digital converter 104 and the control circuit 106 lower than the operating frequency of the sensing circuit 102 may greatly reduce the power consumption of the capacitive sensing device. In addition, the capacitive sensing device of this embodiment may include the digital low-pass filter circuit 402 as shown in the embodiment of FIG. 4 to perform low-pass filtering on the digital sensing signal 51.

To sum up, the control circuit of the embodiments of the disclosure may adjust the capacitance value of the adjustable capacitor unit according to the digital sensing signal obtained by converting the sensing signal by the analog-to-digital converter, so that the capacitance value of the adjustable capacitor unit approaches the background parasitic capacitor, which may prevent the sensing result of the capacitive sensing device from being influenced by changes in the electric field in the environment and having a sensing error, thereby improving the sensing quality of the capacitive sensing device. In some embodiments, the capacitive sensing device may further include a switched capacitance low-pass filter circuit, and by making the operating frequency of the analog-to-digital converter lower than the operating frequency of the sensing circuit and the switched capacitance low-pass filter circuit, and making the operating frequency of the control circuit lower than the operating frequency of the analog-to-digital converter, it may effectively reduce the power consumption of the capacitive sensing device.

Although the disclosure has been disclosed above with embodiments, they are not intended to limit the disclosure. Any person skilled in the art may make some changes and modifications without departing from the spirit and scope of the disclosure. Therefore, the scope of protection of the disclosure shall be defined by the claims and their equivalents.

What is claimed is:

1. A capacitive sensing device, comprising:
a sensing electrode, configured to receive a touch operation by a touch tool;
a sensing circuit, configured to have an input terminal coupled to the sensing electrode through a sensing signal line and sense a change in a sensing capacitor between the touch tool and the sensing electrode to generate a sensing signal, wherein the sensing circuit comprises:
a first switch, coupled between a power supply voltage and the input terminal;
a second switch, having one terminal coupled to the input terminal, and an other terminal of the second switch being coupled to an output terminal of the sensing circuit;
a third switch, coupled between the other terminal of the second switch and a ground, wherein the first switch, the second switch and the third switch periodically switch their being turned on and off, respectively, wherein when the first switch and the third switch are turned on, the second switch is turned off, and when the second switch is turned on, the first switch and the third switch are turned off; and
an adjustable capacitor unit, coupled between the other terminal of the second switch and the ground;
an analog-to-digital converter, coupled to the sensing circuit and configured to convert the sensing signal into a digital sensing signal; and
a control circuit, coupled to the sensing circuit and the analog-to-digital converter and configured to adjust a capacitance value of the adjustable capacitor unit according to the digital sensing signal, so that the capacitance value of the adjustable capacitor unit approaches a background parasitic capacitor.

2. The capacitive sensing device according to claim 1, further comprising:
a switched capacitance low-pass filter circuit, coupled to the sensing circuit and the analog-to-digital converter and configured to perform low-pass filtering on the sensing signal.

3. The capacitive sensing device according to claim 2, wherein an operating frequency of the switched capacitance low-pass filter circuit is greater than an operating frequency of the analog-to-digital converter, and the operating frequency of the analog-to-digital converter is greater than an operating frequency of the control circuit.

4. The capacitive sensing device according to claim 3, wherein the operating frequency of the switched capacitance low-pass filter circuit is 1 MHz, the operating frequency of the analog-to-digital converter is 500 Hz, and the operating frequency of the control circuit is 50 Hz.

5. The capacitive sensing device according to claim 2, wherein the switched capacitance low-pass filter circuit comprises:
a fourth switch, having one terminal coupled to the output terminal of the sensing circuit;
a first capacitor, coupled to an other terminal of the fourth switch;
a fifth switch, having one terminal coupled to the other terminal of the fourth switch, and an other terminal of the fifth switch being coupled to the analog-to-digital converter; and
a second capacitor, coupled between the other terminal of the fifth switch and the ground, wherein the fourth switch and the fifth switch periodically switch their being turned on and off, respectively, so that the switched capacitance low-pass filter circuit performs low-pass filtering on the sensing signal, wherein when the fourth switch is turned on, the fifth switch is turned off, and when the fifth switch turned on, the fourth switch is turned off

6. The capacitive sensing device according to claim 5, wherein a capacitance value of the second capacitor is greater than a capacitance value of the first capacitor.

7. The capacitive sensing device according to claim 1, wherein the control circuit comprises a digital integrating circuit, which generates an integrated value according to the digital sensing signal, and adjusts the capacitance value of the adjustable capacitor unit according to the integrated value and a target value.

8. The capacitive sensing device according to claim 7, wherein when the integrated value is greater than the target value, the control circuit increases the capacitance value of the adjustable capacitor unit, and when the integrated value is less than the target value, the control circuit decreases the capacitance value of the adjustable capacitor unit.

9. The capacitive sensing device according to claim 1, further comprising:
a digital low-pass filter circuit, coupled between the analog-to-digital converter and the control circuit and configured to perform low-pass filtering on the digital sensing signal.

10. The capacitive sensing device according to claim 1, wherein the adjustable capacitor unit comprises:
a plurality of fourth switches, wherein one terminal of each of the fourth switches is coupled to the other terminal of the second switch; and
a plurality of capacitors, respectively coupled between the other terminal of the corresponding fourth switch and the ground, wherein the control circuit controls the plurality of fourth switches to be turned on or off to adjust the capacitance value of the adjustable capacitor unit.
